(19) United States
(12) Patent Application Publication
(10) Pub. No.: US 2011/0001188 A1
(43) Pub. Date: Jan. 6, 2011

(54) SEMICONDUCTOR APPARATUS AND METHOD OF MANUFACTURING THE SAME

(76) Inventor: Akihito Tanabe, Tokyo (JP)

Correspondence Address: Mr. Jackson Chen, 6535 N. STATE HWY 161, IRVING, TX, 75039, US

(21) Appl. No.: 12/919,548

(22) PCT Filed: Mar. 11, 2009
(86) PCT No.: PCT/JP2009/054678

§ 371 Date: Aug. 26, 2010

(30) Foreign Application Priority Data
Mar. 14, 2008 (JP) 208-065927

(51) Int. Cl. H01L 29/78; H01L 21/336

(52) U.S. Cl. 257/335; 438/286; 257/E29.256; 257/E21.417

(57) ABSTRACT

An impact ionization MISFET includes: a gate insulating film which has one surface contacting the surface of a semiconductor substrate; a gate electrode that contacts the other surface of the gate insulating film; and a drain region, channel region, impact ionization region, and source region that are formed in one direction on the semiconductor substrate. The channel region is on the surface of the semiconductor substrate to which the gate insulating film is in contact, and a channel is generated when a voltage is applied to the gate electrode. When a voltage is applied between the drain region and the source region and when a channel is generated in the channel region, avalanche multiplication of carriers injected from the source region occurs in the impact ionization region. The flow path of the carriers between the channel and the source region occurs within the semiconductor substrate.

### TECHNICAL FIELD

The present invention relates to a semiconductor apparatus such as an impact-ionization MIS (Metal-Insulator-Semiconductor) type field effect transistor using avalanche multiplication as the operation principle and to a manufacturing method thereof. Hereinafter, the “MIS type field effect transistor” is simply referred to as “MISFET (MIS Field Effect Transistor)”. MOS (Metal-Oxide-Semiconductor) is also included in MIS as a matter of course. Further, it is to be noted that atomic symbols are used for names of chemical elements.

### BACKGROUND ART

Avalanche multiplication means that the number of carriers (electrons and positive holes) multiplies as in an occurrence of an avalanche because the carriers repeat impact ionization in a high-field semiconductor. As a semiconductor element using the principle of the avalanche multiplication, an impact ionization MISFET is proposed (Non-Patent Document 1). The impact ionization MISFET is a semiconductor element in which such a characteristic that the currents flowing between the source and drain drastically increase due to the avalanche multiplication is applied to drastic increase of the on-off characteristic, and it is expected to be employed as a new semiconductor switch that can be used instead of MISFET that has been used up to this point.

Hereinafter, by referring to FIG. 14, the structure and actions of the impact ionization MISFET will be described. While a bulk Si substrate is used in FIG. 14, an SOI substrate is used in Non-Patent Document 1 instead of the bulk Si substrate. However, there is no difference in both cases in terms of the operation principle of the impact ionization MISFET.

FIG. 14 is a schematic sectional view of a planar-type impact ionization MISFET. FIG. 14A shows an off state, and FIG. 14B shows an on state.

An impact ionization MISFET 100 includes a semiconductor substrate 101, a gate insulating film 102, a gate electrode 103, a drain region 104, a channel region 105, an impact ionization region 106, a source region 107, and the like.

In the channel region 105, a channel 105a is generated when a specific voltage is applied to the gate electrode 103. When a specific voltage is applied between the drain region 104 and the source region 107 and the channel 105a is generated in the channel region 105, avalanche multiplication of carriers 108 injected from the source region 107 occurs in the impact ionization region 106. Then, in the impact ionization region 106 between the channel 105a and the source region 107, a flow path 109 of the carriers 108 is on the surface of the semiconductor substrate 101. The flow path 109 of the carriers 108 is illustrated by being slightly isolated from the surface of the semiconductor substrate 101 for the sake of the drawing.

The semiconductor substrate 101 is a p-type Si substrate with a low impurity concentration, the drain region 104 is an n-type with a high impurity concentration, and the source region 107 is a p-type with a high impurity concentration. The surface of the gate electrode 103 and the surface of the semiconductor substrate 101 are covered by an insulating film 110.

As shown in FIG. 14A, in the off state, the channel 105a is not formed in the channel region 105 under the gate insulating film 102. When a potential difference (Vds) between the drain and the source is increased under a condition where the drain voltage Vd is higher than the source voltage Vs, i.e., in a reverse bias, most voltages are added to the channel region 105 and the impact ionization region 106 between the drain region 104 and the source region 107. Thus, when Vds becomes sufficiently large, the channel region 105 and the impact ionization region 106 are completely depleted. The drain current in that state becomes a reverse saturated current in the reverse bias state of P-I-N junction, so that almost no drain current flows.

In the meantime, when the gate voltage Vg is increased gradually in a state where Vds is set to a voltage of somewhat high level, the channel region 105 under the gate insulating film 102 becomes inverted and the channel region 105a is formed, as shown in FIG. 14B. Thereby, the effective width in the lateral direction of a depletion layer formed in the channel region 105 and the impact ionization region 106 becomes narrower for the length of the channel 105a, so that the electric field intensity within the depletion layer is increased. As a result, the electrons that are the carriers 108 injected from the source region 107 to the narrowed depletion layer (i.e., the impact ionization region 106) cause impact ionization. The drain current is drastically increased since the impact ionization occurs serially (avalanche multiplication) in the depletion layer.

Therefore, the voltage Vds between the drain and the source is set to be within a range with which the impact ionization does not occur when the channel 105a is not formed and with which the impact ionization occurs when the channel 105a is formed.

Hereinafter, a gate voltage required for forming the channel 105a is called “gate threshold voltage”, and a drain-source voltage Vds required for causing impact ionization in a state where the channel 105a is formed is called “drain threshold voltage”. Further, as described above, out of the semiconductor substrate 101 between the drain region 104 and the source region 107, the region where the channel 105a is formed due to an increase in the gate voltage is called the channel region 105, and a region where the channel 105a is not formed is called the impact ionization region 106.

The drain threshold voltage depends on the material and the length of the impact ionization region 106. For example, the impact ionization rate is greater with the ones with a narrow band gap such as SiGe and Ge compared to Si, so that the drain threshold voltage thereof is smaller. Further, when the length of the impact ionization region 106 is shorter, the electric field thereof is increased. Thus, the drain threshold voltage thereof is small. For making the drain threshold voltage equal to or less than 1 V, it is necessary to form the impact ionization region 106 in 50 nm or less by using Ge as the material, for example.

Non-Patent Document 1: K. Gopalakrishnan et al., “I-MOS: A Novel Semiconductor Device with a Subthreshold Slope lower than kT/q”, IEDM Technical Digest, pp. 289-292, December 2002. (particularly, p. 290, Device Structure and Physics, FIG. 2)

### DISCLOSURE OF THE INVENTION

### Problems to be Solved by the Invention

However, the channel 105a is formed only on the surface of the semiconductor substrate 101 like a typical MOSFET. Further, most of the carriers 108 between the channel 105a and the source region 107 transmit on the interface between the insulating film 110 and the semiconductor substrate 101. Therefore, influences of surface roughness dispersions and the like work to prevent the impact ionization of the carries 108 because the flow path 109 of the carriers 108 becomes the surface of the semiconductor substrate 101, which results in increasing the drain threshold voltage. When the drain threshold voltage is high, the carriers 108 with high energy enter the gate insulating film 102. Thus, shift in the gate threshold voltage and the like occur, thereby causing issues such as degradation of the reliability and increase in the leak current in an off state.

An object of the present invention is to provide a semiconductor apparatus such as an impact ionization MISFET which can decrease the drain threshold voltage.

### Means for Solving the Problems

The semiconductor apparatus according to the present invention includes a drain region, a channel region, an impact ionization region, and a source region, which are formed with a semiconductor, and a gate part provided to the channel region. It is characterized that when a channel is generated in the channel region, avalanche multiplication of carriers injected from the source region occurs in the impact ionization region, and a flow path of the carriers is inside the semiconductor.

The semiconductor apparatus manufacturing method according to the present invention is a method of manufacturing a following semiconductor apparatus. The semiconductor apparatus includes a drain region, a channel region, an impact ionization region, and a source region, which are formed with a semiconductor, and a gate insulating film and a gate electrode provided to the channel region, wherein when a channel is generated in the channel region, avalanche multiplication of carriers injected from the source region occurs in the impact ionization region. The semiconductor apparatus manufacturing method according to the present invention is characterized to execute: a first step which forms the gate insulating film and the gate electrode at a position to be the channel region on a surface of the semiconductor; a second step which forms a recessed part by etching the surface of the semiconductor; and a third step which forms the source region in the recessed part.

### EFFECT OF THE INVENTION

In the present invention, the flow paths of the carriers in the impact ionization region between the channel and the source region are formed inside the semiconductor. Thus, the carriers are not affected by the semiconductor surface roughness dispersions and the like, so that the drain threshold voltage can be decreased.

### BEST MODES FOR CARRYING OUT THE INVENTION

Hereinafter, an impact ionization MISFET will be described as a best mode of a semiconductor apparatus according to the present invention.

### First Exemplary Embodiment

FIG. 1 is a schematic sectional view showing an impact ionization MISFET according to a first exemplary embodiment of the invention. Hereinafter, explanations will be provided by referring to the drawing.

An impact ionization MISFET 10 includes a drain region 14, a channel region 15, an impact ionization region 16 as well as a source region 17 which are formed with a semiconductor, and a gate insulating film 12 and a gate electrode 13 as a gate section provided to the channel region 15. When a channel 15a is generated in the channel region 15, avalanche multiplication of carriers 18 injected from the source region 17 occurs in the impact ionization region 16, and a flow path 19 of the carriers 18 is inside the semiconductor in the impact ionization region 16.

In the exemplary embodiment, a semiconductor substrate 11 is used as the semiconductor. Therefore, one face of the gate insulating film 12 is in contact with the surface of the semiconductor substrate 11, and the other face thereof is in contact with the gate electrode 13. The drain region 14, the channel region 15, the impact ionization region 16, and the source region 17 are formed on the semiconductor substrate 11 in one direction (from the left to the right). The channel region 15 is on the surface of the semiconductor substrate 11 to which the gate insulating film 12 is in contact, and a channel 15a is generated when a specific voltage is applied to the gate electrode 13. The flow path 19 of the carriers 18 is inside the semiconductor substrate 11.

With the impact ionization MISFET 10, the flow path 19 of the carriers 18 is formed inside the semiconductor substrate 11 in the impact ionization region 16 between the channel 15a and the source region 17. Thus, the carriers 18 are not affected by the surface roughness dispersion and the like of the semiconductor substrate 11, so that the drain threshold voltage can be decreased.

The channel region 15 and the impact ionization region 16 are of a first conductive type or of an intrinsic type. The drain region 14 is of a second conductive type, and it is formed on the semiconductor substrate 11 in such a manner that a part thereof overlaps with the gate electrode 13 by sandwiching the gate insulating film 12 therebetween. The source region 17 is of the first conductive type, and it is formed on the semiconductor substrate 11 so as not to overlap with the gate electrode 13 by sandwiching the gate insulating film 12 therebetween. In the exemplary embodiment, the first conductive type is defined as the p-type, and the second conductive type is defined as the n-type which is inversed conductive type of the p-type. It is also possible to define the first conductive type as the n-type, and the second conductive type as the p-type. The semiconductor substrate 11 is a first conductive Si substrate.

It is defined here that a normal to the interface between the channel region 15 and the gate insulating film 12 is a coordinate axis Z, the origin of the coordinate of the interface is O, and the coordinate in the direction of the gate insulating film 12 is positive. In that state, a coordinate Zs on the surface closest to the channel 15a and in parallel to the channel 15a in the source region 17 becomes negative. That is, the surface of the semiconductor substrate 11 in the source region 17 is in a structure that is dug from the other surface of the semiconductor substrate 11. In the impact ionization MISFET 100 shown in FIG. 14B, “Zs=0”.

A part 17a of the source region 17, which is closest to the channel 15a, is formed inside the semiconductor substrate 11. That is, the part 17a is projected in a convex form towards the channel 15a. Therefore, the part 17a comes to have the highest electric field, so that the carriers 18 are injected to the impact ionization region 16 from the part 17a. Thereby, the flow path 19 of the carriers 18 can be formed inside the semiconductor substrate 11.

Hereinafter, the impact ionization MISFET 10 will be described in more details.

The n-type drain region 14 and the p-type source region 17 each having the impurity concentration of 1×10²⁰ cm⁻³ or more are formed in the p-type semiconductor substrate 11 with a low impurity concentration. The gate insulating film 12 as well as the gate electrode 13 and an insulating film 20 whose aperture is used for forming the source region 17 are formed in a part on the semiconductor substrate 11 between the drain region 14 and the source region 17. That is, the surface of the gate electrode 13 and the surface of the semiconductor substrate 11 are covered by the insulating film 20.

On the impact ionization MISFET 10, an interlayer insulating film covering the element separating region and the entire part, a silicide layer on each surface of the gate electrode 13, the drain region 14, and the source region 17, wirings for the gate electrode 13, the drain region 14, and the source region 17, and the like are provided. However, those are not directly related to the present invention, so that illustrations thereof are omitted.

As shown in the drawings, the source region 17 is provided at a position that is dug from the surface of the original semiconductor substrate 11. That is, the entire source region 17 is located at a position lower than the interface between the insulating film 20 and the semiconductor substrate 11. Here, the source region 17 is taken as a grounding potential, a positive voltage of equal to or more than the drain threshold voltage is applied to the drain region 14, and a positive voltage of equal to or more than the gate threshold voltage is applied to the gate electrode 13. Upon this the channel 15a is formed in the channel region 15 under the gate electrode 13, and the carriers 18 transmit in the impact ionization region 16. Thereby, the impact ionization MISFET 10 turns into an on state. However, the carriers 18 flow inside the semiconductor substrate 11.

With the impact ionization MISFET 100 shown in FIG. 14B, the carriers 108 are affected by the surface dispersion and the like because the carriers 108 flow on the interface between the insulating film 110 and the semiconductor substrate 101, thereby causing an issue of increasing the drain threshold voltage. In the meantime, with the exemplary embodiment, the carriers 18 flow inside the semiconductor substrate 11. Therefore, the carriers 18 are not affected by the surface dispersion and the like, so that the drain threshold voltage can be decreased. Further, the part 17a of the source region 17, which opposes to the channel region 15, has a large curvature, i.e., small radius curvature, so that electric fields tend to concentrate therein. With this, the drain threshold voltage can be decreased further. To be able to decrease the drain threshold voltage means to be able to decrease the driving voltage, so that it is possible to improve the reliability and to decrease the leak current.

While the impact ionization region 16 is formed with Si, SiGe and Ge with smaller band gap than Si may be used to form the impact ionization region 16. In that case, the impact ionization rate is higher with SiGe and Ge than Si, so that the drain threshold voltage can be decreased more. While Si is used for the semiconductor substrate 11, it is also possible to use an SOI (Silicon on Insulator) substrate in which an insulating film such as an Si oxidation film is formed under Si, an SGOI (Silicon germanium on Insulator) substrate and a GOI (Germanium on Insulator) substrate in which an insulating film such as an Si oxidation film is formed under SiGe or Ge, etc. While the impact ionization MISFET 10 is defined as the n-channel type, it is also possible to use the p-channel type by inverting each conductive type. As evident from the explanations above, in order to achieve the effects of the present invention, the coordinate (almost Zs) of the source region in contact with the impact ionization region may simply need to be negative. Therefore, the coordinate on the surface of the source region closer to the source region than that (on the right side in FIG. 1) does not need to be negative essentially and does not need to be flat as in FIG. 1.

FIG. 2 and FIG. 3 are schematic sectional views showing a manufacturing method of the impact ionization MISFET according to the first exemplary embodiment. Hereinafter, explanations will be provided by referring to those drawings.

First, as shown in FIG. 2A, an insulating film such as an Si oxidation film and a poly Si film are deposited on the surface of the p-type semiconductor substrate 11 whose impurity concentration is 1×10¹⁵ cm⁻³ or less. Thereafter, the gate insulating film 12 and the gate electrode 13 are formed by using a typical photolithography technique and a typical etching technique.

Subsequently, as shown in FIG. 2B, a resist mask 21 is formed, and the drain region 14 is formed by ion-implanting As with an acceleration energy of about 30 keV and a dose amount of 1×10¹⁴ cm⁻² or more. Thereafter, the resist mask 21 is removed.

Subsequently, as shown in FIG. 3C, an Si oxidation film is deposited to form a resist mask 22. Then, the insulating film 20 is formed by using the etching technique, and a recessed part 11a is formed by digging the semiconductor substrate 11 for about 50 nm.

Subsequently, as shown in FIG. 3D, a high-concentration p-region 17b is formed in the recessed part 11a by ion-implanting BF, with an acceleration energy of about 15 keV and a dose amount of 1×10¹⁴ cm⁻² or more via the resist mask 22.

At last, as shown in FIG. 1, a heat treatment of 1000 degrees C. is conducted for about ten seconds to disperse B into the semiconductor substrate 11 from the high-concentration p-region 17b so as to form the source region 17. Thereby, the impact ionization MISFET 10 shown in FIG. 1 is completed.

As described above, the manufacturing method of the impact ionization MISFET 10 includes following three steps. First step: The gate insulating film 12 and the gate electrode 13 are formed at the position to be the channel region 15 on the surface of the semiconductor substrate 11 (FIG. 2A). Second step: The recessed part 11a is formed by etching the surface of the semiconductor substrate 11 (FIG. 3C). Third Step: The source region 17 is formed in the recessed part 11a (FIG. 3D). By including those steps, the flow path 19 of the carriers 18 can be formed inside the semiconductor substrate 11. The order of the first step to the third step may be changed in any order, as long as the impact ionization MISFET 10 can be manufactured at last.

### Second Exemplary Embodiment

FIG. 4 is a schematic sectional view showing an impact ionization MISFET according to a second exemplary embodiment of the invention. Hereinafter, explanations will be provided by referring to the drawing.

An impact ionization MISFET 30 includes a drain region 34 a channel region 35, an impact ionization region 36 as well as a source region 37, which are formed with a semiconductor, and a gate insulating film 32 and a gate electrode 33 provided to the channel region 35. When a channel 35a is generated in the channel region 35, avalanche multiplication of carriers 38 injected from the source region 37 occurs in the impact ionization region 36, and a flow path 39 of the carriers 38 is inside the semiconductor.

In the exemplary embodiment, a semiconductor substrate 31 is used as the semiconductor. Therefore, one face of the gate insulating film 32 is in contact with the surface of the semiconductor substrate 31, and the other face thereof is in contact with the gate electrode 33. The drain region 34, the channel region 35, the impact ionization region 36, and the source region 37 are formed on the semiconductor substrate 31 in one direction (from the left to the right). The channel region 35 is on the surface of the semiconductor substrate 31 to which the gate insulating film 32 is in contact, and a channel 35a is generated when a specific voltage is applied to the gate electrode 33. The flow path 39 of the carriers 38 is inside the semiconductor substrate 31.

With the impact ionization MISFET 30, the flow path 39 of the carriers 38 is formed inside the semiconductor substrate 31 in the impact ionization region 36 between the channel 35a and the source region 37. Thus, the carriers 38 are not affected by the surface roughness dispersion and the like of the semiconductor substrate 31, so that the drain threshold voltage can be decreased.

The channel region 35 and the impact ionization region 36 are of a first conductive type or of an intrinsic type. The drain region 34 is of a second conductive type, and it is formed on the semiconductor substrate 31 in such a manner that a part thereof overlaps with the gate electrode 33 by sandwiching the gate insulating film 32 therebetween. The source region 37 is of the first conductive type, and it is formed on the semiconductor substrate 31 so as not to overlap with the gate electrode 33 by sandwiching the gate insulating film 32 therebetween. In the exemplary embodiment, the first conductive type is defined as the p-type, and the second conductive type is defined as the n-type which is inversed conductive type of p-type. It is also possible to define the first conductive type as the n-type, and the second conductive type as the p-type. The semiconductor substrate 31 is a first conductive Si substrate.

It is defined here that a normal to the interface between the channel region 35 and the gate insulating film 32 is a coordinate axis Z, the origin of the coordinates of the interface is O, and the coordinate in the direction of the gate insulating film 32 is positive. In that state, a coordinate Ys of the interface between the semiconductor substrate 31 in the impact ionization region 36 and the insulating film 40 is positive. That is, the surface of the semiconductor substrate 31 in the impact ionization region 36 is in a structure that is protruded from the surface of the semiconductor substrate 31 in the channel region 35. In the impact ionization MISFET 100 shown in FIG. 14B, “Ys=0”. Note here that while a coordinate Zs' on the surface of the source region 37 shown in FIG. 4 is smaller than Ys mentioned above, those may be the same. Further, the coordinate Zs of the interface between the source region 37 and the substrate 31 may take any values as long as it is smaller than the coordinate Zs' of the surface.

The interface between the semiconductor substrate 31 of the impact ionization region 36 and the insulating film 40 is formed on the higher position than the interface between the channel region 35 and the gate insulating film 32. Therefore, the shortest distance between the source region 37 and the channel 35a is inside the semiconductor substrate 31. Further, a corner part 37a of the source region 37 has a large curvature, i.e., small radius curvature, and the part 37a comes to have the highest electric field when Zs is “0” or larger. Therefore, the carriers 38 are injected into the impact ionization region 36 from the part 37a. Thereby, the flow path 39 of the carriers 38 is formed inside the semiconductor substrate 31.

Hereinafter, the impact ionization MISFET 30 will be described in more details.

The n-type drain region 34 and the p-type source region 37 each having the impurity concentration of 1×10²⁰ cm⁻³ or more are formed in the p-type semiconductor substrate 31 with a low impurity concentration. The gate insulating film 32 as well as the gate electrode 33 and an insulating film 40 whose aperture is used for forming the source region 37 are formed in a part on the semiconductor substrate 31 between the drain region 34 and the source region 37. That is, the surface of the insulating film 49 on the gate electrode 33 and the surface of the semiconductor substrate 31 are covered by the insulating film 40.

A part of the surface of the impact ionization region 36 is formed in the direction of the gate electrode 33 side with respect to the interface between the gate insulating film 32 and the channel region 35 on the basis of the normal direction to the interface i.e., on the upper direction. The position of the surface of the source region 37 is lower than the interface between the insulating film 40 and the semiconductor substrate 31, as in the case of the first exemplary embodiment. A sidewall 41 made with an Si oxide film or the like is formed on the side face of the gate electrode 33.

On the impact ionization MISFET 30, an interlayer insulating film covering the element separating region and the entire part, a silicide layer on each surface of the gate electrode 33, the drain region 34, and the source region 37, wirings for the gate electrode 33, the drain region 34, and the source region 37, and the like are provided. However, those are not directly related to the present invention, so that illustrations thereof are omitted.

As shown in the drawings, the entire source region 37 and the channel region 35 are located at positions lower than the interface between the insulating film 40 and the semiconductor substrate 31. Here, the source region 37 is taken as a grounding potential, a positive voltage of equal to or more than the drain threshold voltage is applied to the drain region 34, and a positive voltage of equal to or more than the gate threshold voltage is applied to the gate electrode 33. Upon this, the channel 35a is formed in the channel region 35 under the gate electrode 33, and the carriers 38 transmit in the impact ionization region 36. Thereby, the impact ionization MISFET 30 turns into an on state. However, the carriers 38 flow inside the semiconductor substrate 31.

With the impact ionization MISFET 100 shown in FIG. 14B, the carriers 108 are affected by the surface dispersion and the like because the carriers 108 flow on the interface between the insulating film 110 and the semiconductor substrate 101, thereby causing an issue of increasing the drain threshold voltage. In the meantime, with the exemplary embodiment, the carriers 38 flow inside the semiconductor substrate 31. Therefore, the carriers 38 are not affected by the surface dispersion and the like, so that the drain threshold voltage can be decreased. Further, the part 37a of the source region 37, which opposes to the channel region 35, has a large curvature, i.e., small radius curvature, so that electric fields tend to concentrate therein. With this, the drain threshold voltage can be decreased further when Zs is “0” or larger. To be able to decrease the drain threshold voltage means to be able to decrease the driving voltage, so that it is possible to improve the reliability and to decrease the leak current. While the source region 37 is located at a position higher than the channel 35a in FIG. 4, the coordinate of the interface between the source region 37 and the substrate 31 may be at any positions, i.e., may be at a position lower than the channel 35a.

While the impact ionization region 36 is formed with Si, SiGe and Ge with smaller band gap than Si may be used to form the impact ionization region 36. In that case, the impact ionization rate is higher with SiGe and Ge than Si, so that the drain threshold voltage can be decreased more. As will be described later, out of the impact ionization region 36, the region formed at a position higher than the channel region 35 is formed by epitaxial growth. This region may be formed as an epitaxial layer of SiGe or Ge instead of Si. In that case, the semiconductor substrate 31 may also be formed with SiGe or Ge like the epitaxial layer. The epitaxial growth using the same material as that of the semiconductor substrate 31 can suppress generation of defects such as dislocation. While an Si substrate is used for the semiconductor substrate 31, it is also possible to use an SOI substrate, an SGOI substrate, a GOI substrate, and the like. While the impact ionization MISFET 30 is defined as the n-channel type, it is also possible to use the p-channel type by inverting each conductive type.

FIG. 5-FIG. 7 are schematic sectional views showing a manufacturing method of the impact ionization MISFET according to the second exemplary embodiment. Hereinafter, explanations will be provided by referring to those drawings.

First, as shown in FIG. 5A, an insulating film such as an Si oxidation film, a poly Si film, and an insulating film such as an Si nitride film are deposited on the surface of the p-type semiconductor substrate 31 whose impurity concentration is 1×10¹⁵ cm⁻³ or less. Thereafter, the gate insulating film 32, the gate electrode 33, and the insulating film 49 are formed by using a typical photolithography technique and a typical etching technique. Then, a high-concentration n-type region 34a is formed on the surface of the semiconductor substrate 31.

First, as shown in FIG. 5B, an insulating film such as an Si oxidation film is formed on the entire surface of the semiconductor substrate 31 including the gate electrode 33, and the sidewall 41 is formed by etching back the insulating film.

Subsequently, as shown in FIG. 6C, a non-dope Si layer 42 with a thickness of 50-100 nm is formed by selective epitaxial growth on the surface where the semiconductor substrate 31 is exposed, other than the insulating film 49 and the sidewall 41.

Subsequently, as shown in FIG. 6D, As is ion-injected after forming a resist mask 43 to form a high-concentration n-type region 34b on the high-concentration n-type region 34a. Thereafter, the resist mask 43 is removed. The high-concentration n-type regions 34a and 34b are integrated at last by a heat treatment to function as the drain region 34.

Subsequently, as shown in FIG. 7E, a resist mask 44 is formed after depositing an Si oxidation film. Then, the insulating film 40 is formed by using an etching technique, and the non-dope Si layer 42 is dug to form a recessed part 42a. However, it is also possible to select as appropriate a structure in which the non-dope Si layer 42 is not dug in. In such case, a recessed part may be formed in the semiconductor substrate 31 as in the case of the first exemplary embodiment by etching the entire non-dope Si layer 42 and further digging the semiconductor substrate 31.

Subsequently, as shown in FIG. 7F, a high-concentration p-type region 37b is formed by ion-implanting BF₂ with an acceleration energy of about 15 keV and a dose amount of 1×10¹⁴ cm⁻² or more via the resist mask 44. Thereafter, the resist mask 44 is removed.

At last, in order to activate the ion-injected impurity, a heat treatment of 1000 degrees C. is conducted for about ten seconds. As a result, as shown in FIG. 4, B is dispersed into the non-dope Si layer 42 and the semiconductor substrate 31 from the high-concentration p-region 37b, thereby forming the source region 37. In this manner, the impact ionization MISFET 30 is completed. The region of the non-dope Si layer 42 formed in FIG. 6C is included in the semiconductor substrate 31 in FIG. 4.

As described above, the manufacturing method of the impact ionization MISFET 30 includes following two steps. First step: The gate insulating film 32 and the gate electrode 33 are formed at the position to be the channel region 35 on the surface of the semiconductor substrate 31 (FIG. 5A). Second step: The non-dope Si layer 42 as the semiconductor epitaxial layer is stacked on the surface of the semiconductor substrate 31, and the impact ionization region 36 is formed at a position higher than the interface between the semiconductor substrate 31 and the gate insulating film 32 (FIG. 6C-FIG. 7F). By including those steps, the flow path 39 of the carriers 38 can be formed inside the semiconductor substrate 31. The order of the first step to the second step may be changed, as long as the impact ionization MISFET 30 can be manufactured at last.

### Third Exemplary Embodiment

FIG. 8 is a schematic sectional view showing an impact ionization MISFET according to a third exemplary embodiment of the invention. Hereinafter, explanations will be provided by referring to the drawing.

An impact ionization MISFET 50 includes a drain region 54, a channel region 55, an impact ionization region 56 as well as a source region 57, which are formed with a semiconductor, and a gate insulating film 52 and a gate electrode 53 provided to the channel region 55. When a channel 55a is generated in the channel region 55, avalanche multiplication of carriers 58 injected from the source region 57 occurs in the impact ionization region 56, and a flow path 59 of the carriers 58 is inside the semiconductor.

In the exemplary embodiment, an Si epitaxial layer 51 is used as the semiconductor. Therefore, one face of the gate insulating film 52 is in contact with the surface of the side of the Si epitaxial layer 51, and the other face thereof is in contact with the gate electrode 53. The drain region 54, the channel region 55, the impact ionization region 56, and the source region 57 are formed on the Si epitaxial layer 51 in one direction (from the bottom to the top). The channel region 55 is on the surface of the Si epitaxial layer 51 to which the gate insulating film 52 is in contact, and a channel 55a is generated when a specific voltage is applied to the gate electrode 53. The flow path 59 of the carriers 58 is inside the Si epitaxial layer 51. The “surface” means a face which forms the outer side of an object.

With the impact ionization MISFET 50, the flow path 59 of the carriers 58 between the impact ionization region 56 and the source region 57 is formed inside the Si epitaxial layer 51. Thus, the carriers 58 are not affected by the surface roughness dispersion and the like of the Si epitaxial layer 51, so that the drain threshold voltage can be decreased.

The channel region 55 and the impact ionization region 56 are of a first conductive type or of an intrinsic type. The drain region 54 is of a second conductive type, and it is formed on the Si epitaxial layer 51 in such a manner that a part thereof overlaps with the gate electrode 53 by sandwiching the gate insulating film 52 therebetween. The source region 57 is of the first conductive type, and it is formed on the Si epitaxial layer 51 by being isolated from the gate electrode 53. In the exemplary embodiment, the first conductive type is defined as the p-type, and the second conductive type is defined as the n-type. It is also possible to define the first conductive type as the n-type, and the second conductive type as the p-type.

It is defined here that a normal to the interface between the channel region 55 and the gate insulating film 52 is a coordinate axis X, the origin of the coordinate of the interface is O, and the coordinate in the direction of the gate insulating film 52 is positive. In that state, a coordinate Xs on the face closest to the channel 55a and in parallel to the channel 55a in the source region 57 is negative.

A part 57a of the source region 57, which is closest to the channel 55a, is formed inside the Si epitaxial layer 51. That is, the part 57a is projected in a convex form towards the channel 55a. Therefore, the part 57a comes to have the highest electric field, so that the carriers 58 are injected to the impact ionization region 56 from the part 57a. Thereby, the flow path 59 of the carriers 58 is formed inside the Si epitaxial layer 51.

Hereinafter, the impact ionization MISFET 50 will be described in more details.

The impact ionization MISFET according to the first and second exemplary embodiments is a “lateral type” in which the channel is formed in the direction in parallel to the semiconductor substrate. In the meantime, the impact ionization MISFET 50 according to the third exemplary embodiment is a “longitudinal type” in which the channel 55a is formed in the direction perpendicular to a semiconductor substrate 61. More specifically, the channel 55a is generated perpendicular to the semiconductor substrate 61 in the Si epitaxial layer 51 that is formed on the semiconductor substrate 61.

Specifically, a high-concentration n-type region 62 with As concentration of 1×10¹⁹ cm⁻³ or more is formed in the p-type Si semiconductor substrate 61 with a low impurity concentration. Further, the Si epitaxial layer 51 is formed on the high-concentration n-type region 62. The Si epitaxial layer 51 is configured with the n-type drain region 54 with P-concentration of 1×10²⁰ cm⁻³ or more, a non-dope layer 63, and the p-type source region 57 with B-concentration of 1×10²⁰ cm⁻³ or more in this order from the bottom side. The non-dope layer 63 is configured with the channel region 55 and the impact ionization region 56.

The gate insulating film 52 and the gate electrode 53 are formed on the surface of the side of the drain region 54 and the surface of the side of the non-dope layer 63. Further, insulating films 64, 65, and 66 for electrically insulating the semiconductor substrate 61, the gate electrode 53, the source region 57, and the like are formed.

On the impact ionization MISFET 50, an interlayer insulating film covering the element separating region and the entire part, a silicide layer on each surface of the gate electrode 53, the drain region 54, and the source region 57, wirings for the gate electrode 53, the drain region 54, and the source region 57, and the like are provided. However, those are not directly related to the present invention, so that illustrations thereof are omitted.

With the “lateral-type” impact ionization MISFET according to the first and second exemplary embodiments, the size of the impact ionization region in the current flow direction depends on the positioning accuracy of the photolithography. As described in the section of “BACKGROUND ART”, it is preferable to have the shorter impact ionization region, since the drain threshold voltage is lowered when the impact ionization region becomes shorter. However, due to the advanced michronization, a vast amount of investment in equipment is required for a photolithography device such as an exposure device.

In the meantime, with the “longitudinal type” impact ionization MISFET 50 according to the third exemplary embodiment, the size of the impact ionization region 56 in the current flow direction can be controlled with the film thickness of the insulating film 65 and the position of the bottom face of the source region 57. Therefore, an expensive photolithography H) device and an exposure mask are not required for forming the impact ionization region 56. Further, the accuracy of the film thickness is higher than the positioning accuracy of the photography, and variation thereof is smaller. Therefore, it is possible with the third exemplary embodiment to cut the cost required for forming the impact ionization region and to manufacture the impact ionization region with higher accuracy compared to the cases of the first and second exemplary embodiments.

As shown in the drawings, the source region 57 is formed in the center on the non-dope layer 63. Here, the source region 57 is taken as a grounding potential, a positive voltage of equal to or more than the drain threshold voltage is applied to the drain region 54, and a positive voltage of equal to or more than the gate threshold voltage is applied to the gate electrode 53. Upon this, the channel 55a is formed in the channel region 55 on the side of the gate electrode 53, and the carriers 58 transmit in the impact ionization region 56. Thereby, the impact ionization MISFET 50 turns into an on state. However, the carriers 58 flow inside the Si epitaxial layer 51 in the impact ionization region 56.

With the impact ionization MISFET 100 shown in FIG. 14B, the carriers 108 are affected by the surface dispersion and the like because the carriers 108 flow on the interface between the insulating film 110 and the semiconductor substrate 101 in the impact ionization region 106, thereby causing an issue of increasing the drain threshold voltage. In the meantime, with the exemplary embodiment, the carriers 58 flow inside the Si epitaxial layer 51 in the impact ionization region 56. Therefore, the carriers 58 are not affected by the surface dispersion and the like, so that the drain threshold voltage can be decreased. Further, the bottom face of the source region 57 is gouged into the non-dope layer 63. Therefore, the electric fields are concentrated in a corner part 57a of the bottom face, so that the drain threshold voltage can be decreased further. To be able to decrease the drain threshold voltage means to be able to decrease the driving voltage, so that it is possible to improve the reliability and to decrease the leak current.

While the impact ionization region 56 is formed with Si, SiGe and Ge with smaller band gap than Si may be used to form the impact ionization region 56. In that case, the impact ionization rate is higher with SiGe and Ge than Si, so that the drain threshold voltage can be decreased more. In that case, the drain region 54, the channel region 55, and the source region 57 may also be formed by using SiGe or Ge instead of Si. The semiconductor substrate 61 may also be formed with SiGe or Ge. The epitaxial growth using the same material as that of the semiconductor substrate 61 can suppress generation of defects such as dislocation. While an Si substrate is used for the semiconductor substrate 61, it is also possible to use an SOI substrate, an SGOI substrate, a GOI substrate, and the like. While the impact ionization MISFET 50 is defined as the n-channel type, it is also possible to use the p-channel type by inverting each conductive type.

FIG. 9 and FIG. 10 are schematic sectional views showing a manufacturing method of the impact ionization MISFET according to the third exemplary embodiment. Hereinafter, explanations will be provided by referring to those drawings.

First, as shown in FIG. 9A, the high-concentration n-type region 62 of 1×10¹⁹ cm⁻³ or more is formed on the surface of the semiconductor substrate 61 made with a p-type Si of 1×10¹⁵ cm⁻³ or less by using a typical photolithography technique and a typical ion-implantation technique. Then, the insulating film 64 such as an Si oxide film is formed on the semiconductor substrate 61. Subsequently, a poly Si film in which P of 1×10²⁰ cm⁻³ or more is doped is deposited on the insulating film 64. Then, the poly Si film is patterned to a prescribed form by using the photolithography technique and the etching technique to form the gate electrode 53.

Subsequently, as shown in FIG. 9B, the insulating film 65 made with an Si oxidation film is formed on the gate electrode 53 and on the exposed insulating film 64. Then, a region 67 to which selective epitaxial growth is applied is opened until the high-concentration n-type region 62 is exposed by using the photolithography technique and the etching technique.

Subsequently, as shown in FIG. 10C, the gate electrode 53 is oxidized to form the gate insulating film 52. Then, the drain region 54 made with an Si epitaxial layer in which P of 1×10²⁰ cm⁻³ or more is doped is formed by the selective epitaxial growth, and the non-dope layer 63 made with a non-dope Si epitaxial layer is formed thereafter. At that time, it is also possible to select to have the surface of the non-dope layer 63 aligned with the surface of the insulating film 65 as necessary by using CMP technique.

Subsequently, as shown in FIG. 10D, the insulating film 66 made with an Si oxidation film is formed on the non-dope layer 63 and on the insulating film 65. Then, a region 68 to which selective epitaxial growth is applied is opened in the insulating film 66 by using the photolithography technique and the etching technique. At this time, a recessed part 63a is formed by digging a part of the non-dope layer 63 for about 20 nm. Subsequently, the source region 57 made with an Si epitaxial layer in which B of 1×10²⁰ cm⁻³ or more is doped is formed by the selective epitaxial growth.

Thereby, the impact ionization MISFET 50 shown in FIG. 8 is completed. A heat treatment for activating the ion-injected impurity is performed as appropriate at an adequate point after the last ion-implantation.

In the steps of FIG. 10D, digging of the non-dope layer 63 is not essential. The same structure can be acquired by diffusing B from the source region 57 by using a heat treatment without digging the non-dope layer 63. However, with the heat treatment in this case, the temperatures are limited when using Ge and SiGe or when using a hetero structure in which the materials of the base substrate and the epitaxial layer are different. This is because Ge and SiGe are low in the heat resistability, and dislocation tends to be generated in the hetero structure at high temperatures.

Further, the source region 57 may also be formed by forming a non-dope Si epitaxial layer instead of the epitaxial layer to which B is doped, and by ion-implanting B with the use of the photolithography technique and the ion-implantation technique. In this case, the impurity is diffused in an Si epitaxial layer 81 at the time of performing the heat treatment for activating the ion-injected impurity, and the corner 57a of the source region 57 is formed inside the Si epitaxial layer 81. Therefore, digging of the Si epitaxial layer 81 is not essential as described above.

As described above, the manufacturing method of the impact ionization MISFET 50 includes following three steps. First step: The gate insulating film 52 and the gate electrode 53 are formed at the position to be the channel region 55 on the surface of the side of the non-dope layer 63 as the semiconductor epitaxial layer (FIG. 9A-FIG. 10C). Second step: The recessed part 63a is formed by etching the surface of the center of the upper end of the non-dope layer 63 (FIG. 10D). Third Step: The source region 47 made with the Si epitaxial layer as the semiconductor epitaxial layer is formed in the recessed part 63a (FIG. 10D). By including those steps, the flow path 59 of the carriers 58 can be formed inside the Si epitaxial layer 51. The order of the first step to the third step may be changed in any order, as long as the impact ionization MISFET 50 can be manufactured at last.

### Fourth Exemplary Embodiment

FIG. 11 is a schematic sectional view showing an impact ionization MISFET according to a fourth exemplary embodiment of the invention. Hereinafter, explanations will be provided by referring to the drawing.

An impact ionization MISFET 70 includes a drain region 74 a channel region 75, an impact ionization region 76 as well as a source region 77, which are formed with a semiconductor, and a gate insulating film 72 and a gate electrode 73 provided to the channel region 75. When a channel 75a is generated in the channel region 75, avalanche multiplication of carriers 78 injected from the source region 77 occurs in the impact ionization region 76, and a flow path 79 of the carriers 78 is inside the semiconductor.

In the exemplary embodiment, an Si epitaxial layer 71 is used as the semiconductor. Therefore, one face of the gate insulating film 72 is in contact with the surface of the side of the Si epitaxial layer 71, and the other face thereof is in contact with the gate electrode 73. The drain region 74, the channel region 75, the impact ionization region 76, and the source region 77 are formed on the Si epitaxial layer 71 in one direction (from the bottom to the top). The channel region 75 is on the surface of the semiconductor substrate Si epitaxial layer 71 to which the gate insulating film 72 is in contact, and a channel 75a is generated when a specific voltage is applied to the gate electrode 73. The flow path 79 of the carriers 78 is inside the Si epitaxial layer 71. The “surface” means a face which forms the outer side of an object.

With the impact ionization MISFET 70, the flow path 79 of the carriers 78 between the impact ionization region 76 and the source region 77 is formed inside the Si epitaxial layer 71. Thus, the carriers 58 are not affected by the surface roughness dispersion and the like of the Si epitaxial layer 71, so that the drain threshold voltage can be decreased.

The channel region 75 and the impact ionization region 76 are of a first conductive type or of an intrinsic type. The drain region 74 is of a second conductive type, and it is formed on the Si epitaxial layer 71 in such a manner that a part thereof overlaps with the gate electrode 73 by sandwiching the gate insulating film 72 therebetween. The source region 77 is of the first conductive type, and it is formed on the Si epitaxial layer 71 by being isolated from the gate electrode 73. In the exemplary embodiment, the first conductive type is defined as the p-type, and the second conductive type is defined as the n-type which is inversed conductive type of the p-type. It is also possible to define the first conductive type as the n-type, and the second conductive type as the p-type.

It is defined here that a normal to the interface between the channel region 75 and the gate insulating film 72 is a coordinate axis Z, the origin of the coordinates of the interface is O, and the coordinate in the direction of the gate insulating film 72 is positive. In that state, a coordinate Xs on the face closest to the channel 75a and in parallel to the channel 75a in the source region 77 is negative.

A part 77a of the source region 77, which is closest to the channel 75a, is formed inside the Si epitaxial layer 71. That is, the part 77a is projected in a convex form towards the channel 75a. Therefore, the part 77a comes to have the highest electric field, so that the carriers 78 are injected to the impact ionization region 76 from the part 77a. Thereby, the flow path 79 of the carriers 78 is formed inside the Si epitaxial layer 71.

Hereinafter, the impact ionization MISFET 70 will be described in more details.

The impact ionization MISFET according to the first and second exemplary embodiments is a “lateral type” in which the channel is formed in the direction in parallel to the semiconductor substrate. In the meantime, the impact ionization MISFET 70 according to the fourth exemplary embodiment is a “longitudinal type” in which the channel 75a is formed in the direction perpendicular to a semiconductor substrate 81. More specifically, the channel 75a is generated perpendicular to the semiconductor substrate 81 in the Si epitaxial layer 71 that is formed on the semiconductor substrate 81.

Specifically, a high-concentration n-type region 82 with As-concentration of 1×10¹⁹ cm⁻³ or more is formed in the p-type Si semiconductor substrate 81 with a low impurity concentration. Further, the Si epitaxial layer 71 is formed on the high-concentration n-type region 82. The Si epitaxial layer 71 is configured with the n-type drain region 74 with P-concentration of 1×10²⁰ cm⁻³ or more, a non-dope layer 83, and the p-type source region 77 with B-concentration of 1×10²⁰ cm⁻³ or more in this order from the bottom side. The non-dope layer 83 is configured with the channel region 75 and the impact ionization region 76.

The gate insulating film 72 and the gate electrode 73 are formed on the surface of the side of the drain region 74 and the surface of the side of the non-dope layer 83. Further, insulating films 84 and 85 for electrically insulating the semiconductor substrate 81, the gate electrode 73, the source region 77, and the like are formed.

On the impact ionization MISFET 70, an interlayer insulating film covering the element separating region and the entire part, a silicide layer on each surface of the gate electrode 73, the drain region 74, and the source region 77, wirings for the gate electrode 73, the drain region 74, and the source region 77, and the like are provided. However, those are not directly related to the present invention, so that illustrations thereof are omitted.

With the “lateral-type” impact ionization MISFET according to the first and second exemplary embodiments, the size of the impact ionization region in the current flow direction depends on the positioning accuracy of the photolithography. As described in the section of “BACKGROUND ART”, it is preferable to have the shorter impact ionization region, since the drain threshold voltage is lowered when the impact ionization region becomes shorter. However, due to the advanced michronization, a vast amount of investment in equipment is required for a photolithography device such as an exposure device.

In the meantime, with the “longitudinal type” impact ionization MISFET 70 according to the fourth exemplary embodiment, the size of the impact ionization region 76 in the current flow direction can be controlled with the film thickness of the insulating film 85 and the position of the bottom face of the source region 77. Therefore, an expensive photolithography device and an exposure mask are not required for forming the impact ionization region 76. Further, the accuracy of the film thickness is higher than the positioning accuracy of the photography, and variation thereof is smaller. Therefore, it is possible with the third exemplary embodiment to cut the cost required for forming the impact ionization region and to manufacture the impact ionization region with higher accuracy compared to the cases of the first and second exemplary embodiments.

As shown in the drawings, the source region 77 is formed in the center on the non-dope layer 83. Here, the source region 77 is taken as a grounding potential, a positive voltage of equal to or more than the drain threshold voltage is applied to the drain region 74, and a positive voltage of equal to or more than the gate threshold voltage is applied to the gate electrode 73. Upon this, the channel 75a is formed in the channel region 75 on the side of the gate electrode 73, and the carriers 78 transmit in the impact ionization region 76. Thereby, the impact ionization MISFET 70 turns into an on state. However, the carriers 78 flow inside the Si epitaxial layer 71 in the impact ionization region 76.

With the impact ionization MISFET 100 shown in FIG. 14B, the carriers 108 are affected by the surface dispersion and the like because the carriers 108 flow on the interface between the insulating film 110 and the semiconductor substrate 101 in the impact ionization region 106, thereby causing an issue of increasing the drain threshold voltage. In the meantime, with the exemplary embodiment, the carriers 78 flow inside the Si epitaxial layer 71 in the impact ionization region 76. Therefore, the carriers 78 are not affected by the surface dispersion and the like, so that the drain threshold voltage can be decreased. Further, the bottom face of the source region 77 is gouged into the non-dope layer 73. Therefore, the electric fields are concentrated in a corner part 77a of the bottom face, so that the drain threshold voltage can be decreased further. To be able to decrease the drain threshold voltage means to be able to decrease the driving voltage, so that it is possible to improve the reliability and to decrease the leak current.

While the impact ionization region 76 is formed with Si, SiGe and Ge with smaller band gap than Si may be used to form the impact ionization region 76. In that case, the impact ionization rate is higher with SiGe and Ge than Si, so that the drain threshold voltage can be decreased more. In that case, the drain region 74, the channel region 75, and the source region 77 may also be formed by using SiGe or Ge instead of Si. The semiconductor substrate 81 may also be formed with SiGe or Ge. The epitaxial growth using the same material as that of the semiconductor substrate 81 can suppress generation of defects such as dislocation. While an Si substrate is used for the semiconductor substrate 81, it is also possible to use an SOI substrate, an SGOI substrate, a GOI substrate, and the like. While the impact ionization MISFET 70 is defined as the n-channel type, it is also possible to use the p-channel type by inverting each conductive type.

FIG. 12 and FIG. 13 are schematic sectional views showing a manufacturing method of the impact ionization MISFET according to the fourth exemplary embodiment. Hereinafter, explanations will be provided by referring to those drawings.

First, as shown in FIG. 12A, the high-concentration n-type region 82 of 1×10¹⁹ cm⁻³ or more is formed on the surface of the semiconductor substrate 81 made with a p-type Si of 1×10¹⁵ cm⁻³ or less by using a typical photolithography technique and a typical ion-implantation technique. Then, the insulating film 84 such as an Si oxide film is formed on the semiconductor substrate 81. Subsequently, a poly Si film in which P of 1×10²⁰ cm⁻³ or more is doped is deposited on the insulating film 84. Then, the poly Si film is patterned to a prescribed form by using the photolithography technique and the etching technique to form the gate electrode 73.

Subsequently, as shown in FIG. 12B, the insulating film 85 made with an Si oxidation film is formed on the gate electrode 73 and on the exposed insulating film 84. Then, a region 87 to which selective epitaxial growth is applied is opened until the high-concentration n-type region 82 is exposed by using the photolithography technique and the etching technique.

Subsequently, as shown in FIG. 13C, the gate electrode 73 is oxidized to form the gate insulating film 72. Then, the drain region 74 made with an Si epitaxial layer in which P of 1×10²⁰ cm⁻³ or more is doped is formed by the selective epitaxial growth, and the non-dope layer 83 made with a non-dope Si epitaxial layer is formed thereafter. At that time, it is also possible to select to have the surface of the non-dope layer 83 aligned with the surface of the insulating film 85 as necessary by using CMP technique.

Subsequently, as shown in FIG. 13D, a resist mask 86 having an aperture 88 is formed on the non-dope layer 83 and on the insulating film 85 by using the photolithography technique. Then, the source region 77 configured with a high-concentration p-region is formed by ion-implanting BF₂ with an acceleration energy of about 15 keV and a dose amount of 1×10¹⁴ cm⁻² or more.

Thereafter, a heat treatment of 1000 degrees C. is performed for about ten seconds to activate the ion-injected dopant. Thereby, the impact ionization MISFET 70 shown in FIG. 11 is completed.

As described above, the manufacturing method of the impact ionization MISFET 70 includes following two steps. First step: The gate insulating film 72 and the gate electrode 73 are formed at the position to be the channel region 75 on the surface of the side of the non-dope layer 83 as the semiconductor epitaxial layer (FIG. 12A-FIG. 12C). Second step: The source region 77 is formed by ion-implantation on the surface of the center of the upper end of the non-dope layer 83 as the semiconductor epitaxial layer (FIG. 12D). By including those steps, the flow path 79 of the carriers 78 can be formed inside the epitaxial layer 71. The order of the first step to the second step may be changed, as long as the impact ionization MISFET 70 can be manufactured at last.

### (Others)

While the present invention has been described by referring to the specific exemplary embodiments shown in the drawings, the present invention is not limited only to those exemplary embodiments shown in the drawings. Further, it is to be noted that the present invention includes combinations of a part or the entire part of the structures of each of the above-described exemplary embodiments. The semiconductor apparatus according to the present invention is not limited to the impact ionization MISFET. For example, the semiconductor apparatus according to the present invention includes all the semiconductor apparatuses having the structure depicted in the appended claims, such as an impact ionization MES (Metal Semiconductor) FET whose gate part is formed only with the gate electrode, an impact ionization optical gate transistor whose gate part is formed as a light-receiving part, and an impact ionization sensor whose gate part is formed as a sensor part.

The object of the present invention can also be expressed as follows. The object of the present invention is to provide a semiconductor apparatus whose reliability is increased through decreasing the driving voltage by forming the source as a dig-in type in the impact ionization MISFET that has the carrier avalanche multiplication caused due to ionizing collision as the operation principle.

The structure of the present invention can be expressed as follows. The semiconductor apparatus according to the present invention includes: a gate insulating film provided on the surface of a semiconductor region that is a first conductive band or an intrinsic type; a gate electrode provided on the gate insulating film; a second conductive type high concentration impurity region that is formed in such a manner that a part thereof overlaps with the gate electrode; and a first conductive type high concentration impurity region that is formed by being offset from the gate electrode, wherein the surface of the first conductive type high concentration impurity region is in the direction of the semiconductor region than the surface of the semiconductor region located between the gate electrode and the first conductive type impurity region on the basis of a normal direction with respect to the interface between the gate insulating film and the semiconductor region.

Further, a part of the surface of the semiconductor region located between the gate electrode and the first conductive type high concentration impurity region may be formed in the direction of the gate electrode than the interface between the gate insulating film and the semiconductor region on the basis of the normal direction with respect to the interface. The corner of the first conductive type high impurity region may be formed inside the semiconductor region. The first conductive type high concentration impurity region may be formed by selective epitaxial growth. A part of the semiconductor region located between the gate electrode and the first conductive high concentration impurity region may be formed by the selective epitaxial growth. Out of the semiconductor region, at least the part between the gate electrode and the first conductive high concentration impurity region may be formed with Si, SiGe, or Ge. An insulating film may be formed underneath the semiconductor region.

The effects of the present invention may be expressed as follows. It is possible with the present invention to provide a semiconductor apparatus whose reliability is increased through decreasing the driving voltage in the impact ionization MISFET that has the carrier avalanche multiplication caused due to ionizing collision as the operation principle.

While the present invention has been described by referring to the embodiments (and examples), the present invention is not limited only to those embodiments (and examples) described above. Various kinds of modifications that occur to those skilled in the art can be applied to the structures and details of the present invention within the scope of the present invention.

This Application claims the Priority right based on Japanese Patent Application No. 2008-065927 filed on Mar. 14, 2008 and the disclosure thereof is hereby incorporated by reference in its entirety.

### INDUSTRIAL APPLICABILITY

The present invention can contribute to provide the semiconductor apparatus such as an impact ionization MISFET that is capable of decreasing the drain threshold voltage.

### BRIEF DESCRIPTION OF THE DRAWINGS

FIG. 1 is a schematic sectional view showing an impact ionization MISFET according to a first exemplary embodiment of the invention;

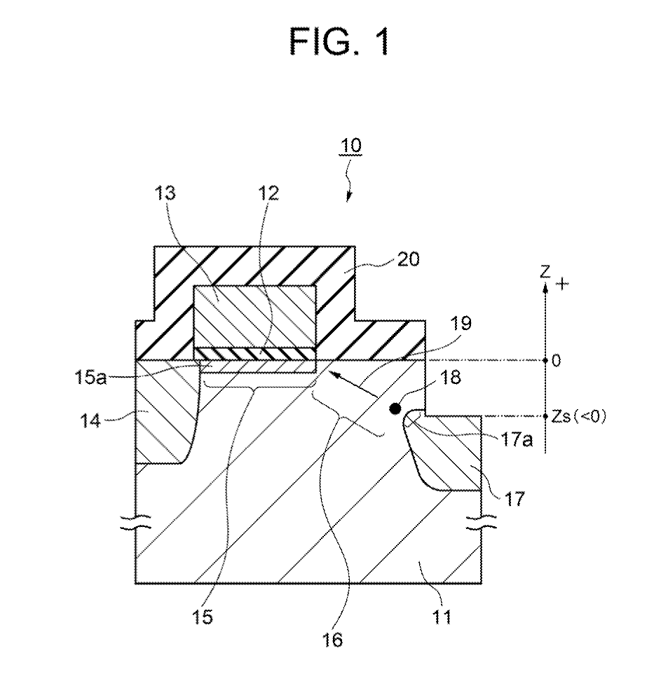

FIG. 2 is a schematic sectional view 1 showing a manufacturing method of the impact ionization MISFET according to the first exemplary embodiment;

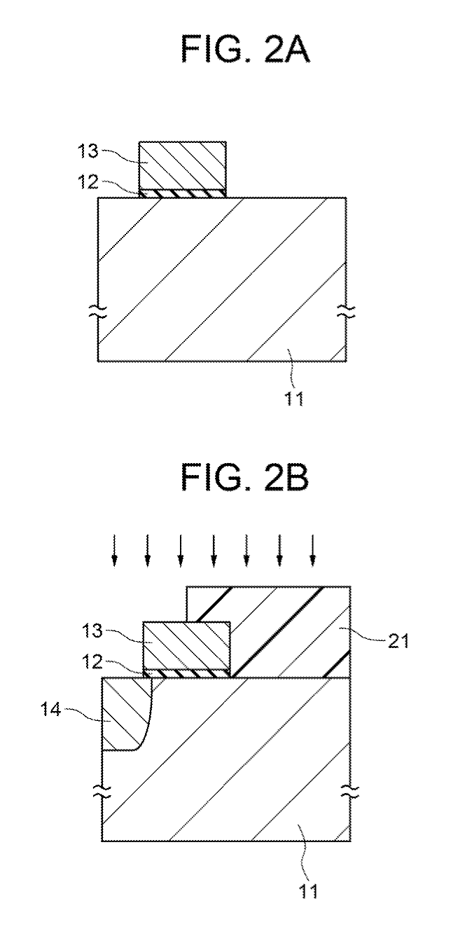

FIG. 3 is a schematic sectional view 2 showing the manufacturing method of the impact ionization MISFET according to the first exemplary embodiment;

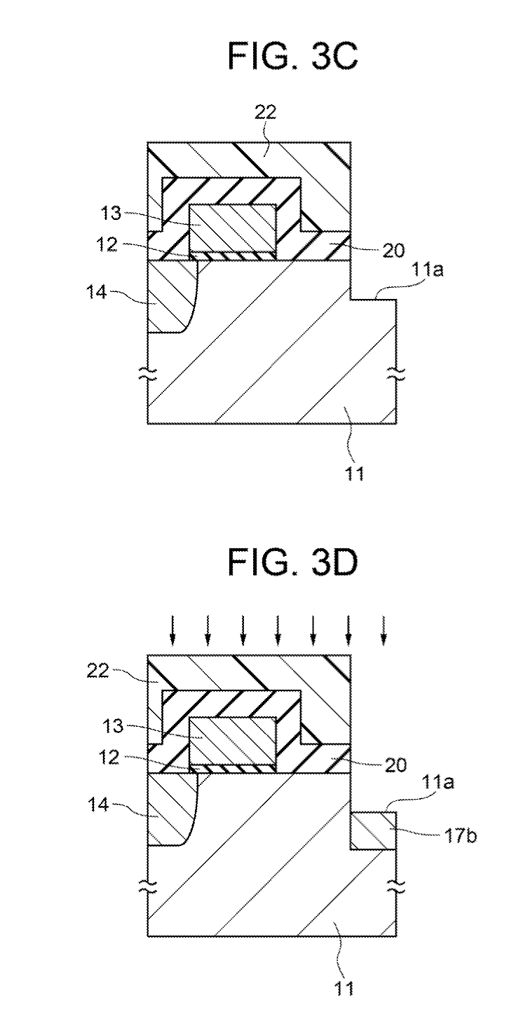

FIG. 4 is a schematic sectional view showing an impact ionization MISFET according to a second exemplary embodiment of the invention;

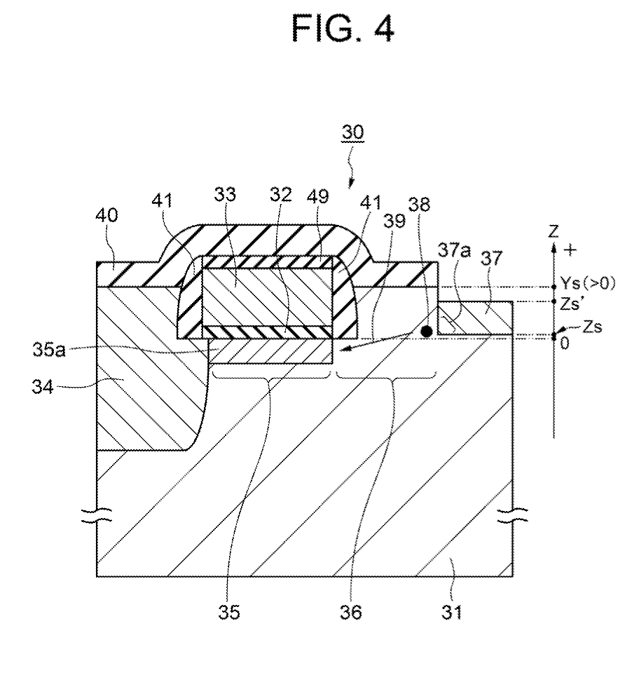

FIG. 5 is a schematic sectional view 1 showing a manufacturing method of the impact ionization MISFET according to the second exemplary embodiment;

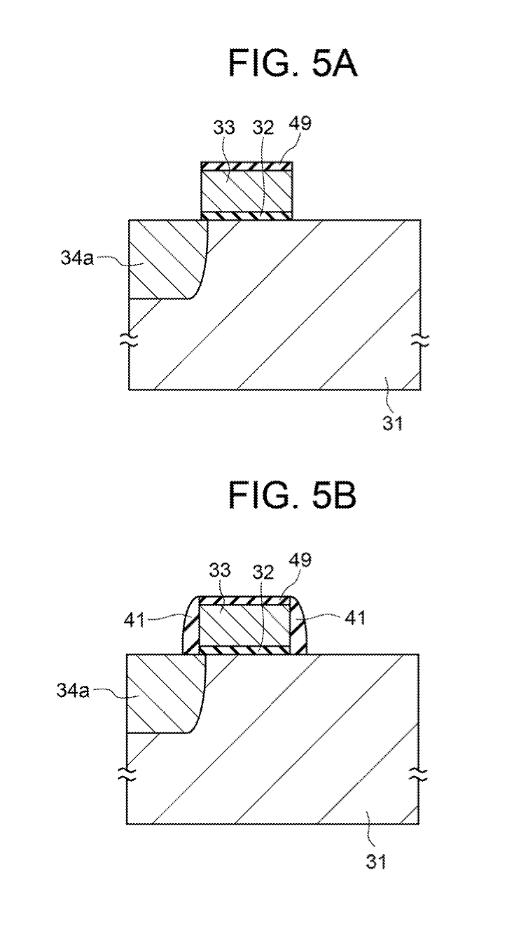

FIG. 6 is a schematic sectional view 2 showing the manufacturing method of the impact ionization MISFET according to the second exemplary embodiment;

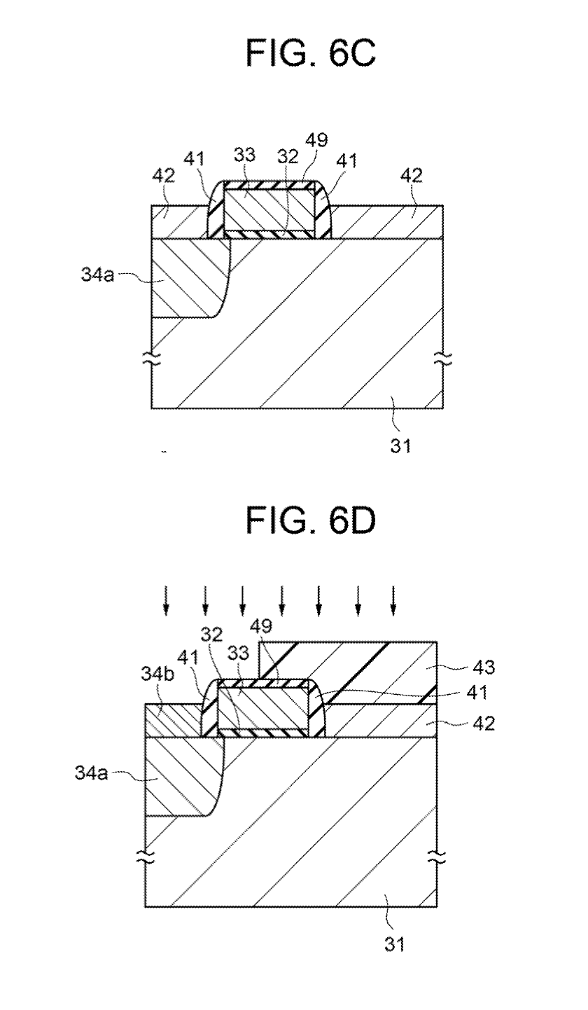

FIG. 7 is a schematic sectional view 3 showing the manufacturing method of the impact ionization MISFET according to the second exemplary embodiment;

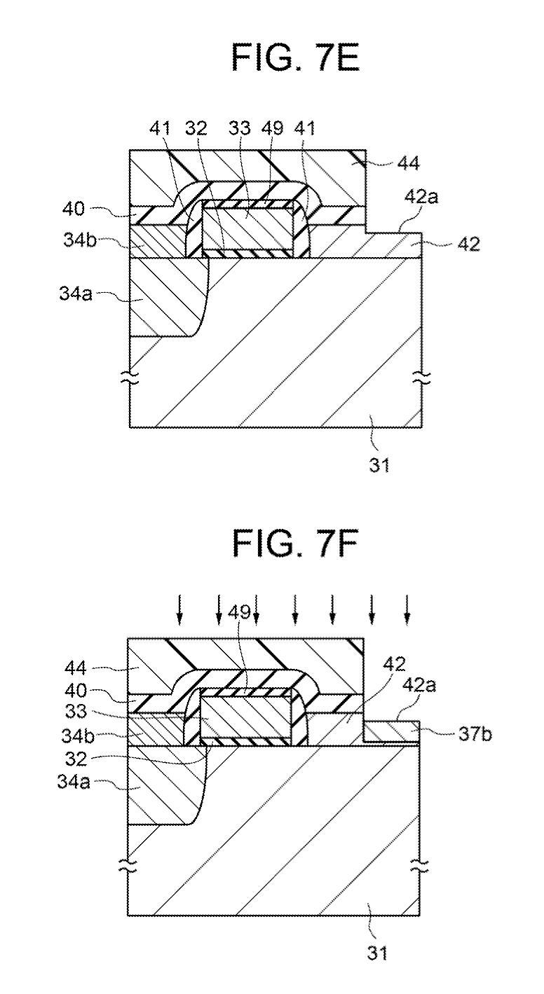

FIG. 8 is a schematic sectional view showing an impact ionization MISFET according to a third exemplary embodiment of the invention;

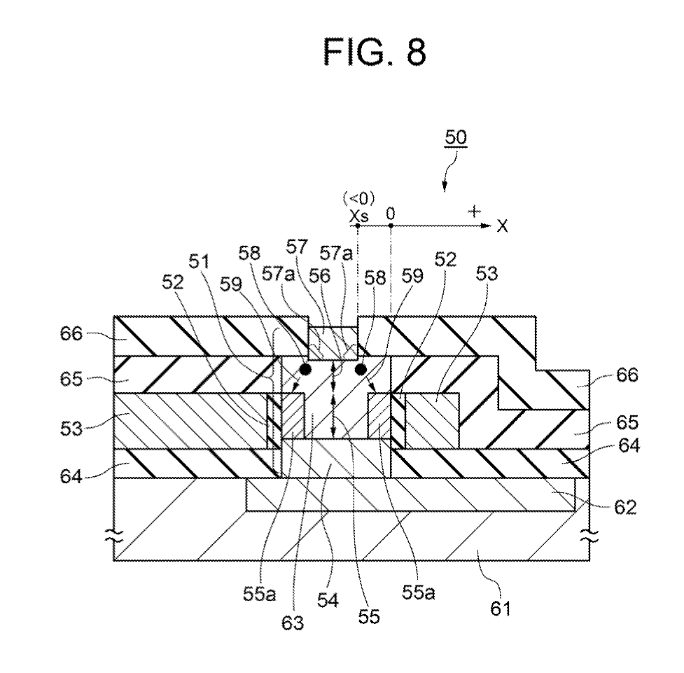

FIG. 9 is a schematic sectional view 1 showing a manufacturing method of the impact ionization MISFET according to the third exemplary embodiment;

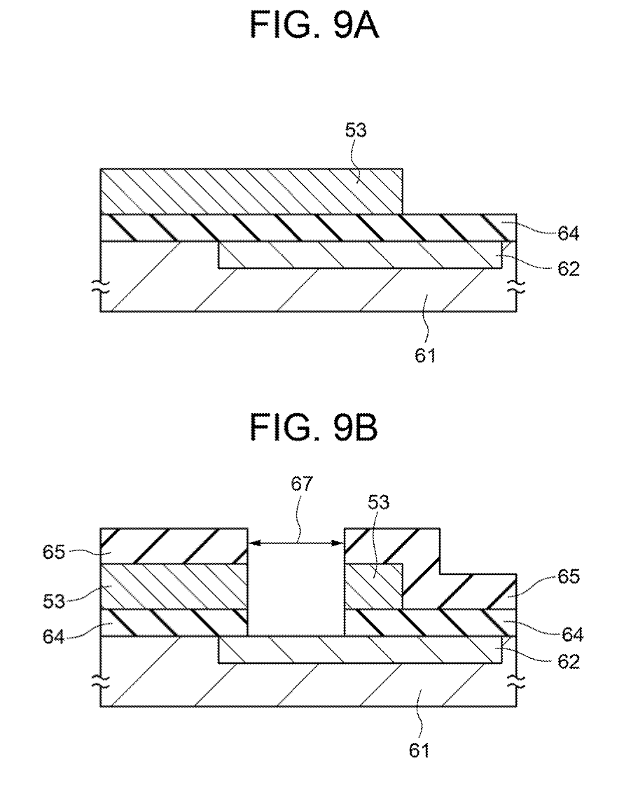

FIG. 10 is a schematic sectional view 2 showing the manufacturing method of the impact ionization MISFET according to the third exemplary embodiment;

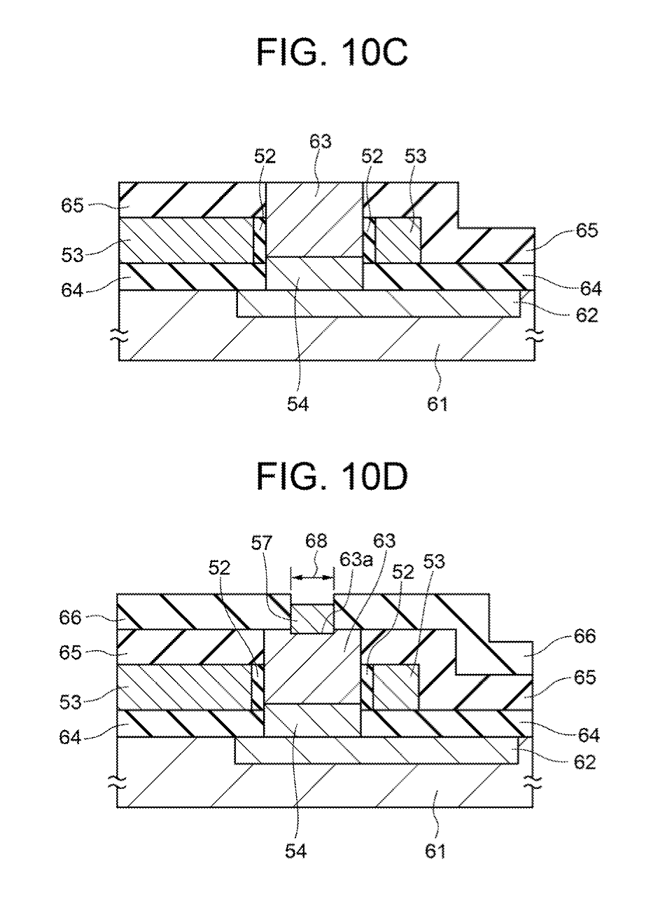

FIG. 11 is a schematic sectional view showing an impact ionization MISFET according to a fourth exemplary embodiment of the invention;

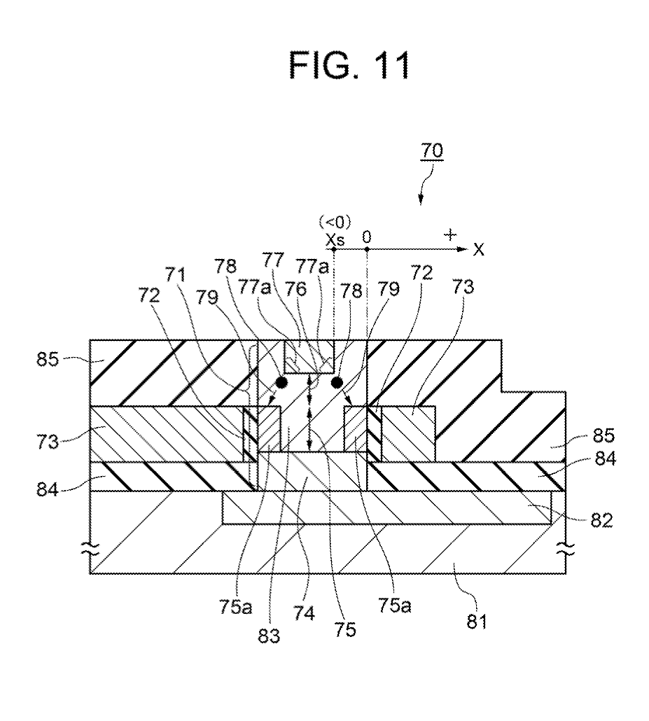

FIG. 12 is a schematic sectional view 1 showing a manufacturing method of the impact ionization MISFET according to the fourth exemplary embodiment;

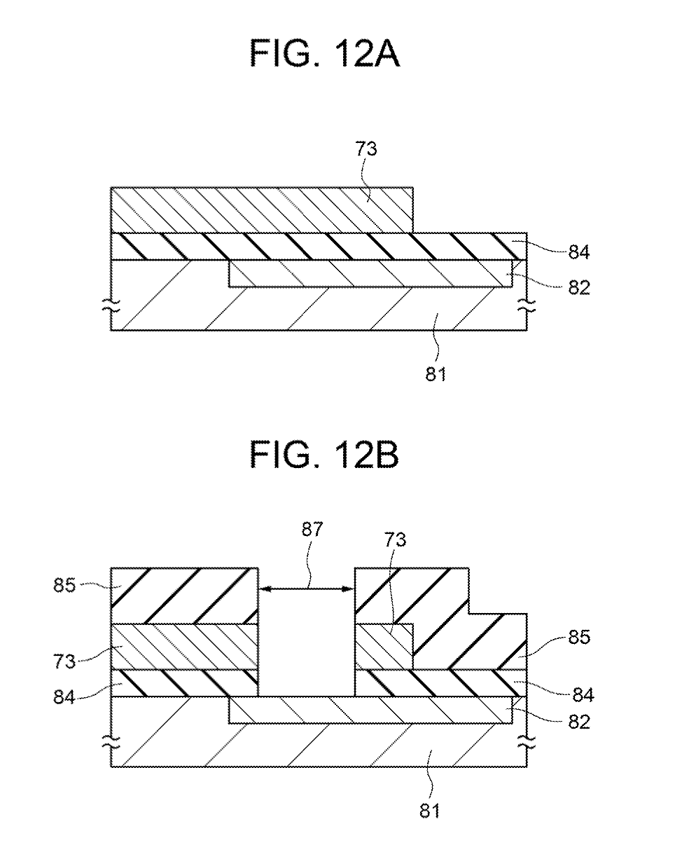

FIG. 13 is a schematic sectional view 2 showing the manufacturing method of the impact ionization MISFET according to the fourth exemplary embodiment; and

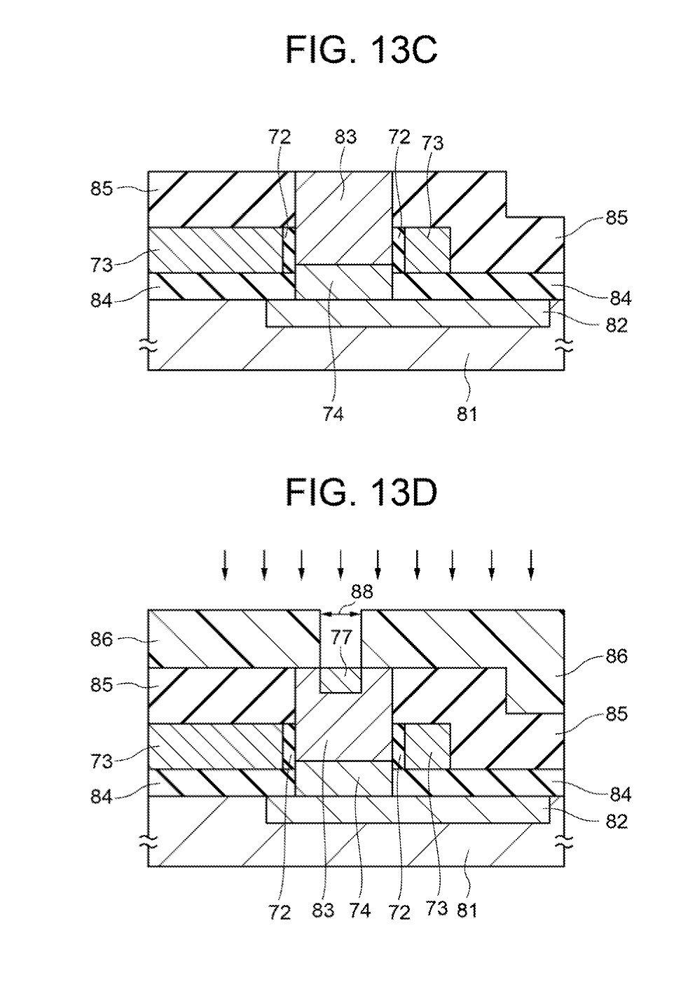

FIG. 14 is a schematic sectional view showing an impact ionization MISFET related to the present invention.

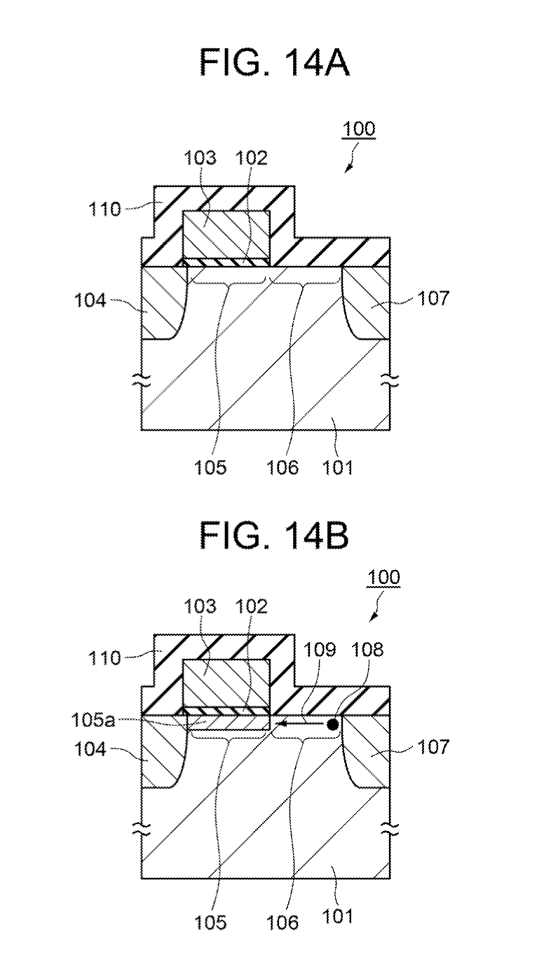

### REFERENCE NUMERALS

10, 30, 50, 70 Impact ionization MISFET (semiconductor apparatus)
11, 31 Semiconductor substrate (semiconductor)
12, 32, 52, 72 Gate insulating film (gate part)
13, 33, 53, 73 Gate electrode (gate part)
14, 34, 54, 74 Drain region
15, 35, 55, 75 Channel region
15a, 35a, 55a, 75a Channel
16, 36, 56, 76 Impact ionization region
17, 37, 57, 77 Source region
18, 38, 58, 78 Carrier
19, 39, 59, 79 Flow path of carrier
51, 71 Si epitaxial layer (semiconductor)

1. A semiconductor apparatus, comprising a drain region, a channel region, an impact ionization region, and a source region, which are formed with a semiconductor, and a gate part provided to the channel region, wherein
when a channel is generated in the channel region, avalanche multiplication of carriers injected from the source region occurs in the impact ionization region, and a flow path of the carriers is inside the semiconductor.

2. The semiconductor apparatus as claimed in claim 1, wherein:
the gate part is formed with a gate insulating film and a gate electrode;
one face of the gate insulating film is in contact with a surface of the semiconductor, and other face is in contact with the gate electrode;
the drain region, the channel region, the impact ionization region, and the source region are formed in the semiconductor in one direction; and
the channel region is on the surface of the semiconductor to which the gate insulating film is in contact, and the channel is generated when a specific voltage is applied to the gate electrode.

3. The semiconductor apparatus as claimed in claim 2, wherein:
the channel region and the impact ionization region are of a first conductive type or of an intrinsic type;
the drain region is of a second conductive type, and is formed on the semiconductor in such a manner that a part thereof overlaps with the gate electrode by sandwiching the gate insulating film therebetween; and
the source region is of the first conductive type, and is formed on the semiconductor so as not to overlap with the gate electrode by sandwiching the gate insulating film therebetween.

4. The semiconductor apparatus as claimed in claim 2 wherein:
provided that a normal to an interface between the channel region and the gate insulating film is a coordinate axis, a coordinate of the interface is an origin, and a coordinate in a direction of the gate insulating film is positive, a coordinate of at least a part of the source region, which is in contact with the impact ionization region, is negative.

5. The semiconductor apparatus as claimed in claim 2 wherein:
provided that a normal to an interface between the channel region and the gate insulating film is a coordinate axis, a coordinate of the interface is an origin, and a coordinate in a direction of the gate insulating film is positive, a coordinate of at least a surface of a region of the impact ionization region, which is in contact with the source region, is positive.

6. The semiconductor apparatus as claimed in claim 1, wherein
a part of the source region, which is closest to the channel region, is formed inside the semiconductor.

7. The semiconductor apparatus as claimed in claim 1, wherein:
the semiconductor is a semiconductor layer formed on a semiconductor substrate; and
the channel is generated in the semiconductor layer vertically with respect to the semiconductor substrate.

8. The semiconductor apparatus as claimed in claim 1, wherein
at least the impact ionization region is formed with Si, SiGe, or Ge.

9. The semiconductor apparatus as claimed in claim 1, wherein
the semiconductor is an SOI (Silicon on Insulator) substrate, an SGOI (Silicon Germanium on Insulator) substrate, or a GOI (Germanium on Insulator) substrate.

10. A manufacturing method of a semiconductor apparatus which comprises a drain region, a channel region, an impact ionization region, and a source region, which are formed with a semiconductor, and a gate insulating film and a gate electrode provided to the channel region, wherein when a channel is generated in the channel region, avalanche multiplication of carriers injected from the source region occurs in the impact ionization region, the method comprising:
a first step which forms the gate insulating film and the gate electrode at a position to be the channel region on a surface of the semiconductor;
a second step which forms a recessed part by etching the surface of the semiconductor; and
a third step which forms the source region in the recessed part.

11. The semiconductor apparatus manufacturing method as claimed in claim 10, wherein
in the second step, a semiconductor epitaxial layer is stacked on the surface of the semiconductor layer, and a surface of the semiconductor epitaxial layer is etched to form the recessed part.

12. A method for forming the semiconductor apparatus claimed in claim 5, the method comprising:
a first step which forms the gate insulating film and the gate electrode at a position to be the channel region on the surface of the semiconductor; and
a second step which stacks a semiconductor epitaxial layer on the surface of the semiconductor.

13. The semiconductor apparatus manufacturing method as claimed in claim 10, wherein:
the semiconductor is a semiconductor epitaxial layer formed in a convex form on a semiconductor substrate;
in the first step, the gate insulating film and the gate electrode are formed at a position to be the channel region on a surface of a side of the semiconductor epitaxial layer;
in the second step, a surface of center of an upper end of the semiconductor epitaxial layer is etched to form the recessed part; and
in the third step, the source region formed with the semiconductor epitaxial layer is formed in the recessed part.

14. The semiconductor apparatus manufacturing method as claimed in claim 10, wherein:
the semiconductor is a semiconductor epitaxial layer formed in a convex form on a semiconductor substrate;
in the first step, the gate insulating film and the gate electrode are formed at a position to be the channel region on a surface of a side of the semiconductor epitaxial layer; and
a step that forms the source region by implanting ions on the surface of center of an upper end of the semiconductor epitaxial layer is employed instead of the second step and the third step.
